(19) United States
(12) Patent Application Publication
(10) Pub. No.: US 2026/0321193 A1
(43) Pub. Date: Oct. 15, 2026

(54) DISPLAY DEVICE AND ELECTRONIC DEVICE

(71) Applicant: Samsung Display Co., Ltd., Yongin-si (KR)

(72) Inventors: Dae Hyun KIM, Yongin-si (KR); Hey Jin SHIN, Yongin-si (KR); Mi Hae KIM, Yongin-si (KR); Joong Soo MOON, Yongin-si (KR); Hyeon Jun YOON, Yongin-si (KR); Young Jin CHO, Yongin-si (KR)

(21) Appl. No.: 19/431,840

(22) Filed: Dec. 23, 2025

(30) Foreign Application Priority Data
Apr. 14, 2025 (KR) 10-2025-0048291

(51) Int. Cl. G09G 3/32; G09G 3/3233

(52) U.S. Cl. CPC G09G 3/32; G09G 3/3233; G09G 2300/0426; G09G 2300/0819

(57) ABSTRACT

A display device of the present disclosure includes a substrate, pixels above the substrate, and including a first transistor including a channel in a first active layer spaced from the substrate by a first distance, and a second transistor including a channel in a second active layer spaced from the substrate by a second distance that is greater than the first distance, and a valley structure between some of the pixels, penetrating insulating layers, and having a lower part spaced from the substrate by a third distance that is less than the second distance and different from the first distance.

### CROSS-REFERENCE TO RELATED APPLICATION

The present application claims priority to, and the benefit of, Korean Patent Application No. 10-2025-0048291, filed on Apr. 14, 2025, in the Korean Intellectual Property Office, the entire disclosure of which is incorporated herein by reference.

### BACKGROUND

### 1. Field

The present disclosure relates to a display device and an electronic device.

### 2. Description of the Related Art

With the development of information technology, the importance of a display device, which is a connection medium between a user and information, increases. Accordingly, display devices, such as a liquid crystal display device and an organic light-emitting display device, are increasingly used.

To implement a narrow bezel, at least one or more sides of the display device may be bent. In addition, various display devices with structures that fold at least partially, such as a foldable display and a rollable display, are being developed. In this case, there is a risk of cracking in the display device due to the stress applied to the display device.

### SUMMARY

An aspect of the present disclosure provides a display device and an electronic that can increase or maximize stress dispersion and reduce or minimize crack occurrence.

A display device according to one or more embodiments of the present disclosure includes a substrate, pixels above the substrate, and including a first transistor including a channel in a first active layer spaced from the substrate by a first distance, and a second transistor including a channel in a second active layer spaced from the substrate by a second distance that is greater than the first distance, and a valley structure between some of the pixels, penetrating insulating layers, and having a lower part spaced from the substrate by a third distance that is less than the second distance and different from the first distance.

The lower part of the valley structure may contact an upper part of the first active layer.

The lower part of the valley structure may contact an upper part of a first conductive layer between the substrate and the first active layer.

The lower part of the valley structure may contact an upper part of a second conductive layer between the first active layer and the second active layer.

The second conductive layer may include a scan line including a gate electrode of the first transistor.

An upper part of the valley structure may be spaced from the substrate by a fourth distance that is greater than the second distance.

The valley structure may include a cover layer covering an upper part, a lower part, and a side wall and including conductive material.

The cover layer may be configured to receive an initialization voltage.

The display device may further include valley structures including the valley structure, wherein the pixels are arranged in a first direction, and in a second direction substantially perpendicular to the first direction, wherein the valley structures extend in at least one of the first direction or the second direction, and wherein a length of the valley structures is greater than a length of the pixels.

The display device may further include valley structures including the valley structure, wherein the pixels are arranged in a first direction, and in a second direction substantially perpendicular to the first direction, wherein the valley structures extend in at least one of the first direction or the second direction, and wherein a length of the valley structures is less than a length of the pixels.

An electronic device according to one or more embodiments of the present disclosure includes a processor for providing an image data, and a display device for displaying an image based on grayscales of the image data, and including a substrate, pixels above the substrate and including a first transistor including a channel in a first active layer spaced from the substrate by a first distance, and a second transistor including a channel in a second active layer spaced from the substrate by a second distance that is greater than the first distance, and a valley structure between some of the pixels, penetrating insulating layers, and having a lower part spaced from the substrate by a third distance that is less than the second distance and that is different from the first distance.

The lower part of the valley structure may contact an upper part of the first active layer.

The lower part of the valley structure may contact an upper part of a first conductive layer between the substrate and the first active layer.

The lower part of the valley structure may contact an upper part of a second conductive layer between the first active layer and the second active layer.

The second conductive layer may include a scan line including a gate electrode of the first transistor.

An upper part of the valley structure may be spaced from the substrate by a fourth distance that is greater than the second distance.

The valley structure may include a cover layer covering an upper part, a lower part, and a side wall and including conductive material.

The cover layer may be configured to receive an initialization voltage.

The display device may include valley structures including the valley structure, wherein the pixels are arranged in a first direction, and in a second direction substantially perpendicular to the first direction, wherein the valley structures extend in at least one of the first direction or the second direction, and wherein a length of the valley structures is greater than a length of the pixels.

The display device may include valley structures including the valley structure, wherein the pixels are arranged in a first direction and in a second direction substantially perpendicular to the first direction, wherein the valley structures extend in at least one of the first direction or the second direction, and wherein a length of the valley structures is less than a length of the pixels.

The display device and the electronic device according to the present disclosure can increase or maximize stress dispersion, and can reduce or minimize crack occurrence.

### BRIEF DESCRIPTION OF THE DRAWINGS

FIG. 1 is a diagram illustrating a display device according to one or more embodiments of the present disclosure.

FIG. 2 is a diagram illustrating a pixel according to one or more embodiments of the present disclosure.

FIGS. 3 to 6 are diagrams illustrating display frequency change according to one or more embodiments of the present disclosure.

FIG. 7 is a diagram illustrating an address scan period according to one or more embodiments of the present disclosure.

FIG. 8 is a diagram illustrating a self-scan period according to one or more embodiments of the present disclosure.

FIG. 9 is a diagram illustrating an auxiliary scan period according to one or more embodiments of the present disclosure.

FIGS. 10 and 11 are diagrams illustrating a relationship between pads, connecting lines, and signal lines according to one or more embodiments of the present disclosure.

FIGS. 12 to 22 are diagrams illustrating a layout of a pixel unit according to one or more embodiments of the present disclosure.

FIGS. 23 to 26 are diagrams illustrating a valley structure according to one or more other embodiments of the present disclosure.

FIGS. 27 to 32 are diagrams to illustrate a relationship between pixels and valley structures according to embodiments of the present disclosure.

FIG. 33 is a block diagram of an electronic device according to one or more embodiments.

FIGS. 34 to 36 are schematic diagrams of an electronic device according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

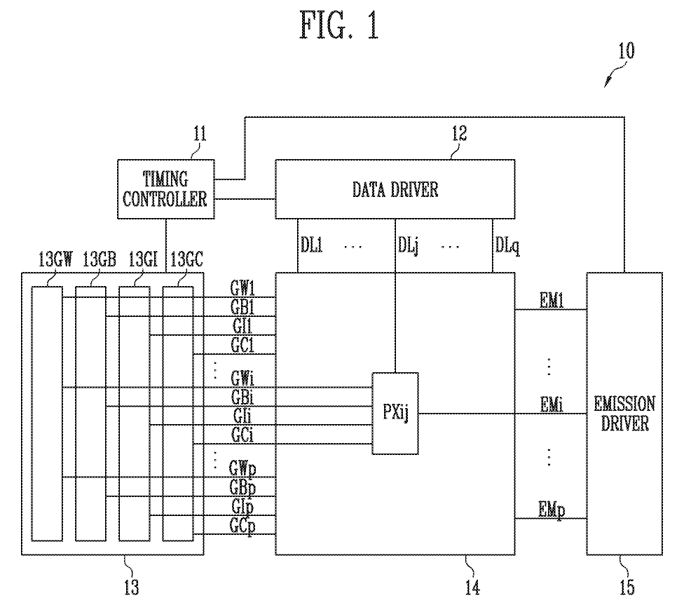

FIG. 1 is a diagram illustrating a display device according to one or more embodiments of the present disclosure.

Referring to FIG. 1, the display device 10 according to one or more embodiments of the present disclosure may include a timing controller 11, a data driver 12, a scan driver 13, a pixel unit 14, and an emission driver 15.

The timing controller 11 may receive grayscales of an input image (or input frame). The grayscales may include a first color grayscale, a second color grayscale, and a third color grayscale. The first color grayscale may be a grayscale for expressing a first color, the second color grayscale may be a grayscale for expressing a second color, and the third color grayscale may be a grayscale for expressing a third color.

Also, the timing controller 11 may receive a control signal for an image. The control signal may include a horizontal synchronization signal Hsync, a vertical synchronization signal Vsync, and a data enable signal. The vertical synchronization signal may include a plurality of pulses, and may indicate that a previous frame period is ended and a current frame period is started with respect to a time at which each of the pulses is generated. An interval between adjacent pulses of the vertical synchronization signal may correspond to one frame period. The horizontal synchronization signal may include a plurality of pulses, and may indicate that a previous horizontal period is ended and a new horizontal period is started with respect to a time at which each of the pulses is generated. An interval between adjacent pulses of the horizontal synchronization signal may correspond to one horizontal period. The data enable signal may have an enable level in specific horizontal periods and have a disable level with respect to the other period. When the data enable signal has the enable level, this indicates that color grayscales are supplied in the corresponding periods.

The timing controller 11 may provide the data driver 12 with grayscales rendered or corrected to be suitable for specifications of the display device 10. Also, the timing controller 11 may provide the scan driver 13 with a clock signal, a scan start signal, and the like. The timing controller 11 may provide the emission driver 15 with a clock signal, an emission stop signal, and the like.

The data driver 12 may generate data voltages to be provided to data lines DL1, …, DLj, …, and DLq, using grayscales and control signals, which are received from the timing controller 11. For example, the data driver 12 may sample grayscales, using a clock signal, and apply data voltages corresponding to the grayscales to the data lines in units of pixel rows. Here, q may be an integer that is larger than 1, and j may be an integer that is larger than 0 and smaller than q.

The scan driver 13 may include first to fourth scan drivers 13GW, 13GB, 13GI, and 13GC. The first scan driver 13GW may provide first scan signals to first scan lines GW1, …, GWi, …, and GWp. Here, p may be an integer that is greater than 1, and i may be an integer greater than 0 and smaller than p. The second scan driver 13GB may provide second scan signals to second scan lines GB1, …, GBi, …, and GBp. The third scan driver 13GI may provide third scan signals to third scan lines GI1, …, GIi, …, GIp. The fourth scan driver 13GC may provide fourth scan signals to fourth scan lines GC1, …, GCi, …, and GCp.

For example, the first scan driver 13GW may generate the first scan signals to be supplied to the first scan lines GW1 to GWp by receiving at least one scan clock signal or a scan start signal from the timing controller 11. The first scan driver 13GW may sequentially provide the first scan signals having a pulse of a turn-on level to the first scan lines GW1 to GWp. For example, the first scan driver 13GW may be configured in the form of shift registers, and generate the first scan signals in a manner that sequentially transfers the scan start signal in the form of a pulse of a turn-on level to a next scan stage under the control of the scan clock signal.

Each of the second scan driver 13GB, the third scan driver 13GI, and the fourth scan driver 13GC may be configured similarly to the first scan driver 13GW, and therefore, repeated overlapping descriptions will be omitted. In some embodiments, at least some of the first to fourth scan drivers 13GW, 13GB, 13GI, and 13GC may be integrated.

The emission driver 15 may generate emission signals to be provided to emission lines EM1, …, EMi, …, and EMp by receiving at least one emission clock signal or an emission stop signal from the timing controller 11. The emission driver 15 may sequentially provide the emission signals having a pulse of a turn-off level to the emission lines EM1 to EMp. For example, the emission driver 15 may be configured in the form of shift registers, and may generate the emission signals in a manner that sequentially transfer the emission stop signal in the form of a pulse of a turn-off level to a next emission stage under the control of the emission clock signal.

In FIG. 1, it is illustrated that the number of each of the first scan lines GW1 to GWp, the second scan lines GB1 to GBp, the third scan lines GI1 to GIp, the fourth scan lines GC1 to GCp, and the emission lines EM1 to EMp is p. However, in one or more other embodiments, the number of at least one of the second scan lines GB1 to GBp, the third scan lines GI1 to GIp, the fourth scan lines GC1 to GCp, or the emission lines EM1 to EMp may be p/2 or less. For example, two adjacent pixel rows may share one second scan line. Similarly, two adjacent pixel rows may share one third scan line, one fourth scan line, or one emission line. The same pixel row means pixels connected to the same first scan line.

The pixel unit 14 (or a display panel) may include pixels. Each pixel PXij may be connected to a corresponding data line DLj, corresponding scan lines GWi, GBi, GIi, and GCi, and a corresponding emission line EMi. Each pixel PXij may include a light-emitting element emitting light, based on a received data voltage.

The pixel unit 14 may include first pixels emitting light of the first color, second pixels emitting light of the second color, and third pixels emitting light of the third color. The first color, the second color, and the third color may be different colors. For example, the first color may be one color among red, green, and blue, the second color may be another color instead of the first color among red, green, and blue, and the third color may be the other color instead of the first color and the second color among red, green, and blue. In addition, magenta, cyan, and yellow instead of red, green, and blue may be used as the first to third colors.

The pixels of the pixel unit 14 may be arranged in various forms such as diamond PENTILE^{TM}, RGB-stripe, S-stripe, real RGB, and normal PENTILE^{TM}(PENTILE^{TM} being a registered trademark of Samsung Display Co., Ltd., Republic of Korea).

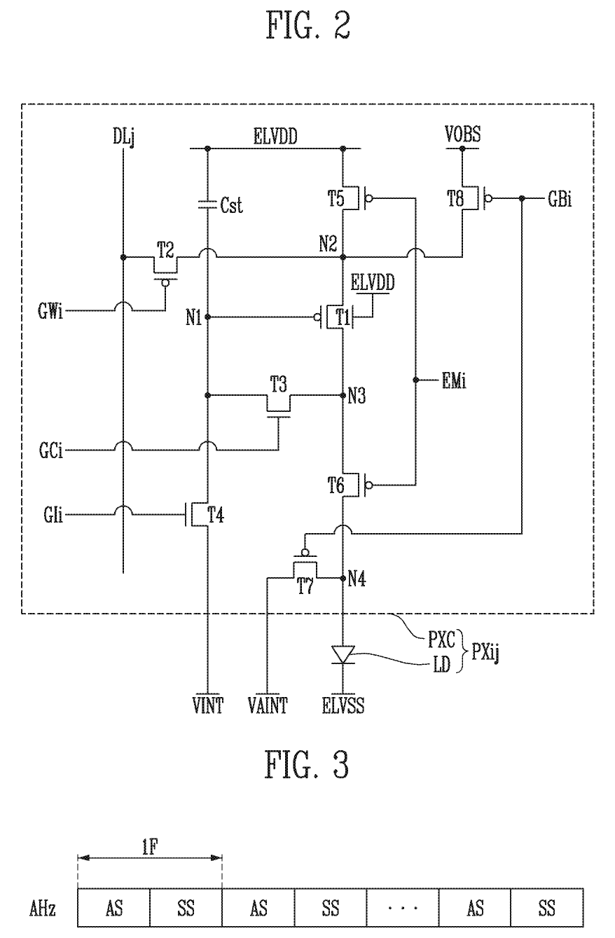

FIG. 2 is a diagram illustrating a pixel according to one or more embodiments of the present disclosure.

Referring to FIG. 2, the pixel PXij may include a pixel circuit PXC and a light-emitting element LD. The pixel circuit PXC may include transistors T1, T2, T3, T4, T5, T6, T7, and T8 and a storage capacitor Cst.

The pixel PXij may be located on an ith pixel row and be located on a jth pixel column. The pixel PXij may be a first pixel for expressing a first color. A second pixel for expressing a second color and a third pixel for expressing a third color may be configured similarly or identically to the first pixel, and therefore, overlapping descriptions will be omitted.

P-type transistors may be poly-silicon semiconductor transistors. In the poly-silicon semiconductor transistor, a channel of an active layer may include a poly-silicon semiconductor. For example, the poly-silicon semiconductor transistor may be a Low Temperature Poly-Silicon (LTPS) thin film transistor. The poly-silicon semiconductor transistor has a high electron mobility, and has a fast driving characteristic according to the high electron mobility.

N-type transistors may be oxide semiconductor transistors. In the oxide semiconductor transistor, a channel of an active layer may include an oxide semiconductor. For example, the oxide semiconductor transistor may be a Low Temperature Polycrystalline Oxide (LTPO) thin film transistor. The oxide semiconductor transistor has a low charge mobility as compared with the poly-silicon semiconductor transistor. Therefore, an amount of leakage current generated in a turn-off state of the oxide semiconductor transistors may be small as compared with the poly-silicon semiconductor transistor.

A gate electrode of a first transistor T1 may be connected to a first node N1, a first electrode of the first transistor T1 may be connected to a second node N2, and a second electrode of the first transistor T1 may be connected to a third node N3. The first transistor T1 may be a driving transistor. The first transistor T1 may be a P-type transistor. According to one or more embodiments, the first transistor T1 may include a sub-gate electrode (or, a back-gate electrode, a body), and the sub-gate electrode may receive a first power voltage ELVDD. According to one or more embodiments, the sub-gate electrode of the first transistor T1 may be connected to the gate electrode (e.g., the first node). According to one or more embodiments, the sub-gate electrode of the first transistor T1 may not be present.

A gate electrode of a second transistor T2 may be connected to a first scan line GWi, a first electrode of the second transistor T2 may be connected to a data line DLj, and a second electrode of the second transistor T2 may be connected to the second node N2.

The first scan driver 13GW may provide a first scan signal, which determines a timing at which the pixel PXij receives a data voltage. For example, the second transistor T2 for receiving the first scan signal of a turn-on level may be turned-on. The second transistor T2 may apply, to the second node N2, a data voltage applied to the data line DLj.

A gate electrode of a third transistor T3 may be connected to a fourth scan line GCi, a first electrode of the third transistor T3 may be connected to the first node N1, and a second electrode of the third transistor T3 may be connected to the third node N3. The third transistor T3 may be a diode connection transistor. The third transistor T3 may be an N-type transistor.

A gate electrode of a fourth transistor T4 may be connected to a third scan line GIi, a first electrode of the fourth transistor T4 may be connected to the first node N1, and a second electrode of the fourth transistor T4 may receive a first initialization voltage VINT. The fourth transistor T4 may be a gate initialization transistor. The fourth transistor T4 may be an N-type transistor.

A gate electrode of a fifth transistor T5 may be connected to an emission line EMi, a first electrode of the fifth transistor T5 may receive the first power voltage ELVDD, and a second electrode of the fifth transistor T5 may be connected to the second node N2. The fifth transistor T5 may be a first emission control transistor. The fifth transistor T5 may be a P-type transistor.

A gate electrode of a sixth transistor T6 may be connected to the emission line EMi, a first electrode of the sixth transistor T6 may be connected to the third node N3, and a second electrode of the sixth transistor T6 may be connected to a fourth node N4. The sixth transistor T6 may be a second emission control transistor. The sixth transistor T6 may be a P-type transistor.

A gate electrode of a seventh transistor T7 may be connected to a second scan line GBi, a first electrode of the seventh transistor T7 may receive a second initialization voltage VAINT (or an anode initialization voltage), and a second electrode of the seventh transistor T7 may be connected to the fourth node N4. The seventh transistor T7 may be an anode initialization transistor. The seventh transistor T7 may be a P-type transistor.

The second scan driver 13GB may provide a second scan signal, which controls a timing at which the second initialization voltage VAINT (or the anode initialization voltage) is provided. For example, the second transistor T7 for receiving the second scan signal of a turn-on level may be turned-on, and the second initialization voltage VAINT may be applied to an anode of the light-emitting element LD, so that the anode voltage of the light-emitting element LD is initialized to the second initialization voltage VAINT.

A gate electrode of an eighth transistor T8 may be connected to the second scan line GBi, a first electrode of the eighth transistor T8 may receive a bias voltage VOBS, and a second electrode of the eighth transistor T8 may be connected to the second node N2. The eighth transistor T8 may be a bias transistor. The eighth transistor T8 may be a P-type transistor.

A first electrode of the storage capacitor Cst may receive the first power voltage ELVDD, and a second electrode of the storage capacitor Cst may be connected to the first node N1.

An anode electrode of the light-emitting element LD may be connected to the fourth node N4, and a cathode electrode of the light-emitting element LD may receive a second power voltage ELVSS. The light-emitting element LD may emit light of one of the first color, the second color, and the third color. The light-emitting element LD may be a light-emitting diode. The light-emitting element LD may be configured as an organic light-emitting diode, an inorganic light-emitting diode, a quantum dot/well light-emitting diode, or the like. One light-emitting element LD is provided in each pixel. However, in one or more other embodiments, a plurality of light-emitting elements may be provided in each pixel. The plurality of light-emitting elements may be connected in series, parallel, series/parallel, or the like.

FIGS. 3 to 6 are diagrams illustrating display frequency change according to one or more embodiments of the present disclosure.

The display device 10 may support a Variable Refresh Rate VRR. A refresh rate is a frequency at which a data voltage is written to the pixel PXij, and is referred to as a screen scan rate or a screen refresh rate. The refresh rate may represent a number of image frames reproduced for one second.

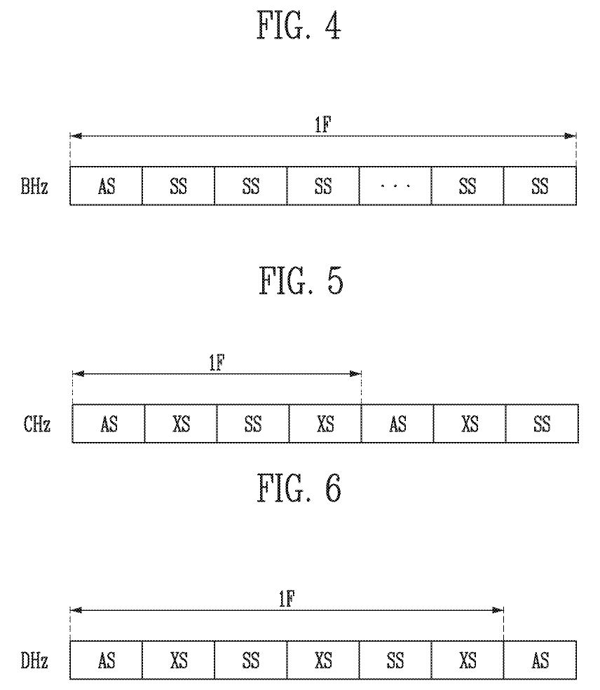

The pixel unit 14 may display an image at a first frequency (AHz) in a first mode (see FIG. 3), and may display an image at a second frequency (BHz) that is lower than the first frequency (AHz) in a second mode (see FIG. 4).

For example, each frame period 1F in the first mode may include one address scan period AS and one self-scan period SS with respect to each pixel PXij. For example, each frame period 1F in the second mode may include one address scan period AS and a plurality of self-scan periods SS with respect to each pixel PXij. As the second frequency (BHz) becomes smaller, the number of self-scan periods SS included in one frame period 1F may increase. In another example, each frame period 1F in a specific mode may include only one address scan period AS with respect to each pixel PXij, while including no self-scan period SS.

The address scan period AS is a period in which a data voltage is written to the pixel PXij. The address scan period AS may be referred to as a data programming period in which a data voltage is received from the data line DLj.

The self-scan period SS is a period in which no data voltage is written to the pixel PXij. During an emission period of the self-scan period SS, the pixel PXij may emit light, using the data voltage written in the address scan period AS. For example, a length of the self-scan period SS may be equal to a length of the address scan period AS.

The pixel unit 14 may display an image at a third frequency (CHz) in a third mode (see FIG. 5), and may display the image at a fourth frequency (DHz) that is less than the third frequency (CHz), in a fourth mode (See FIG. 6).

In the third mode and the fourth mode, an auxiliary scan period XS, that follows the address scan period AS and an auxiliary scan period XS, that follows the self-scan period SS, may be included.

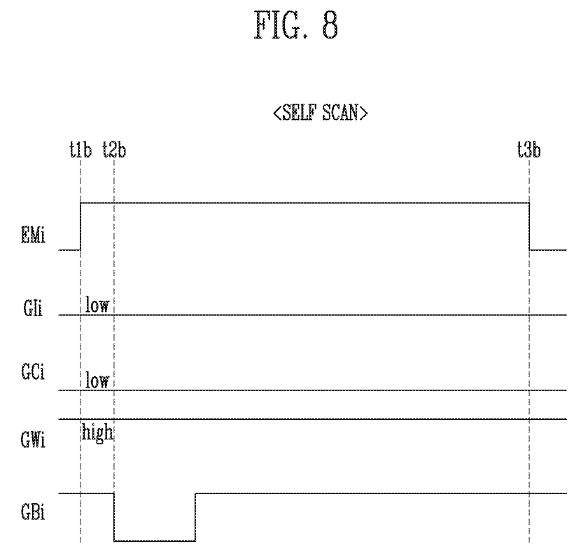

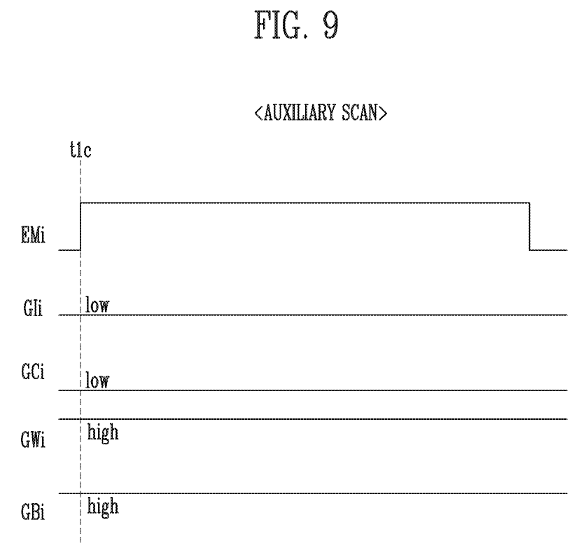

The auxiliary scan period XS may be similar to the self-scan period SS in that it is the period in which the data voltage is not written into the pixel PXij. During an emission period of the auxiliary scan period XS, the pixel PXij may emit light using the data voltage written in the address scan period AS. For example, a length of the auxiliary scan period XS may be the same as the length of the address scan period AS. However, the auxiliary scan period XS differs from the self-scan period SS in that the second scan signal of the turn-on level is not supplied. For this, refer to FIGS. 8 and 9 described later.

The display device 10 does not necessarily have to be driven to include all of the first mode, the second mode, the third mode, and the fourth mode. The display device 10 may also be driven in only at least one mode among the first mode, the second mode, the third mode, or the fourth mode. For example, the display device 10 may be driven in only one mode among the first mode, the second mode, the third mode, and the fourth mode. In addition, the display device 10 may be driven only in the first mode and the second mode, and may not be driven in the third mode and the fourth mode. Meanwhile, the display device 10 may be driven only in the third mode and the fourth mode, and may not be driven in the first mode and the second mode.

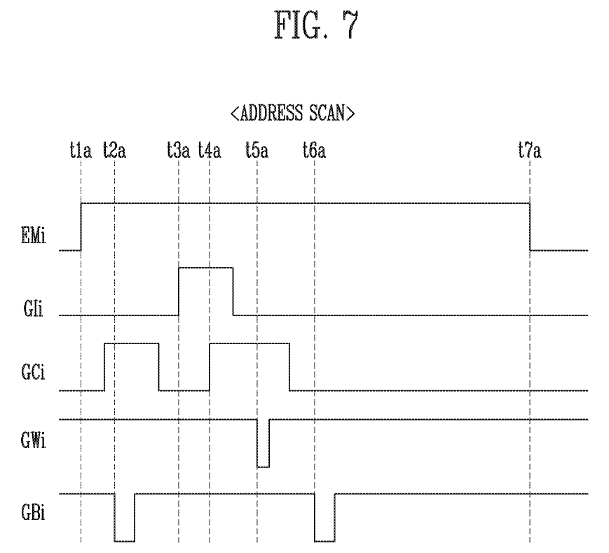

FIG. 7 is a diagram illustrating an address scan period according to one or more embodiments of the present disclosure. In explaining FIG. 7, the pixel PXij of FIG. 2 is referenced.

At a time point t1a, as an emission signal of a turn-off level (high level) is provided to the emission line EMi, the fifth transistor T5 and the sixth transistor T6 are turned-off, and the pixel PXij is in a non-emission state.

At a time point t2a, as a second scan signal of a turn-on level (low level) is provided to the second scan line GBi, the seventh transistor T7 and the eighth transistor T8 are turned-on. In addition, as a fourth scan signal of a turn-on level (high level) is provided to the fourth scan line GCi, the third transistor T3 is turned-on. At this time, the first transistor T1 may be on-biased by providing a bias voltage VOBS higher than a gate electrode (first node N1) to a source electrode (second node N2) of the first transistor T1. When the first transistor T1 is on-bias, a data voltage of a current frame input thereafter may be lower than the bias voltage VOBS. Therefore, a hysteresis phenomenon can be reduced or prevented regardless of a size of a data voltage of a previous frame.

For reference, the hysteresis phenomenon refers to a phenomenon that a source-to-drain current curve versus a gate-to-source voltage of a transistor, when a data voltage of a current frame is higher than a data voltage of a previous frame, differs from a source-to-drain current curve versus a gate-to-source voltage of a transistor when a data voltage of a current frame is lower than a data voltage of a previous frame.

At a time point t3a, as a third scan signal of a turn-on level (high level) is provided to the third scan line GIi, the fourth transistor T4 is turned-on. Accordingly, the first initialization voltage VINT is provided to the first node N1. The first initialization voltage VINT is low enough to make the first transistor T1 into a turn-on state.

At a time point t4a, as a fourth scan signal of a turn-on level (high level) is provided to the fourth scan line GCi, the third transistor T3 is turned-on. Thus, the first transistor T1 is a diode-connected state in which a drain electrode and a gate electrode are connected.

At a time point t5a, as a scan signal of a turn-on level (low level) is provided to the first scan line GWi, the second transistor T2 is turned-on. Thus, a data voltage of the data line DLj may be provided to the first node N1 through the second transistor T2, the first transistor T1, and the third transistor T3, which are in a turn-on state. At this time, a voltage of the first node N1 may be a compensation voltage by subtracting a threshold voltage of the first transistor T1 from the data voltage. The storage capacitor Cst may maintain a difference between the first power voltage ELVDD and the compensation voltage.

At a time point t6a, as a scan signal of the turn-on level (low level) is provided to the second scan line GBi, the seventh transistor T7 and the eighth transistor T8 are turned-on. As the seventh transistor T7 is turned-on, the second initialization voltage VAINT may be provided to the anode of the light-emitting element LD, and the light-emitting element LD may be initialized with a charge corresponding to a voltage difference between the second initialization voltage VAINT and the second power voltage ELVSS. Accordingly, low-grayscale expression of the light-emitting element LD can be facilitated.

At a time point t7a, as an emission signal of a turn-on level (low level) to the emission line EMi, the fifth transistor T5 and the sixth transistor T6 may be turned-on. Therefore, a path of a driving current flowing from the first power voltage ELVDD to the second power voltage ELVSS via the fifth transistor T5, the first transistor T1, the sixth transistor T6, and the light-emitting element LD is formed.

The driving current may be adjusted according to a voltage maintained in the storage capacitor Cst. The light-emitting element LD emits light with a luminance corresponding to the driving current. The light-emitting element LD may emit light until an emission signal of a turn-off level is provided to the emission line EMi.

FIG. 8 is a diagram illustrating a self-scan period according to one or more embodiments of the present disclosure. In explaining FIG. 8, the pixel PXij of FIG. 2 is referenced.

At a time point t1b, as an emission signal of a turn-off level (high level) is provided to the emission line EMi, the fifth transistor T5 and the sixth transistor T6 are turned-off, and the pixel PXij is non-emission state.

During the self-scan period t1b to t3b, scan signals of a turn-off level are maintained in first scan line GWi, the third scan line GIi, and the fourth scan line GCi. Therefore, a voltage of the first node N1 is unchanged.

At a time point t2b, as a scan signal of a turn-on level (low level) is provided to the second scan line GBi, the seventh transistor T7 and the eighth transistor T8 are turned-on. As the seventh transistor T7 is turned-on, the second initialization voltage VAINT may be provided to the anode of the light-emitting element LD, and the light-emitting element LD may be initialized with a charge corresponding to the voltage difference between the second initialization voltage VAINT and the second power voltage ELVSS. Accordingly, low-grayscale expression of the light-emitting element LD can be facilitated.

At a time point t3b, as an emission signal of a turn-on level (low level) is provided to the emission line EMi, the fifth transistor T5 and the sixth transistor T6 may be turned-on. Thus, a path of driving current flowing from the first power voltage ELVDD to the second power voltage ELVSS via the fifth transistor T5, the first transistor T1, the sixth transistor T6, and the light-emitting element LD is formed.

The driving current may be adjusted according to a voltage maintained in the storage capacitor Cst. Because a voltage of the first node N1 recorded during the address scan period AS is maintained during the self-scan period SS, luminance of the light-emitting element LD in the self-scan period SS may be the same as luminance of the light-emitting element LD in the address scan period AS.

FIG. 9 is a diagram illustrating an auxiliary scan period according to one or more embodiments of the present disclosure.

The auxiliary scan period of FIG. 9 is one example of the auxiliary scan period XS of FIGS. 5 and 6. During the auxiliary scan period of FIG. 9, an emission signal in the emission line EMi may have the same waveform as the signals in the address scan period in FIG. 7. However, first to fourth scan signals may maintain a turn-off level. Accordingly, a voltage of the first node N1 is unchanged, and a voltage difference between two ends of the storage capacitor Cst may be maintained. Therefore, luminance of the light-emitting element LD after the auxiliary scan period of FIG. 9 may be the same as luminance of light-emitting element LD after the address scan period immediately preceding.

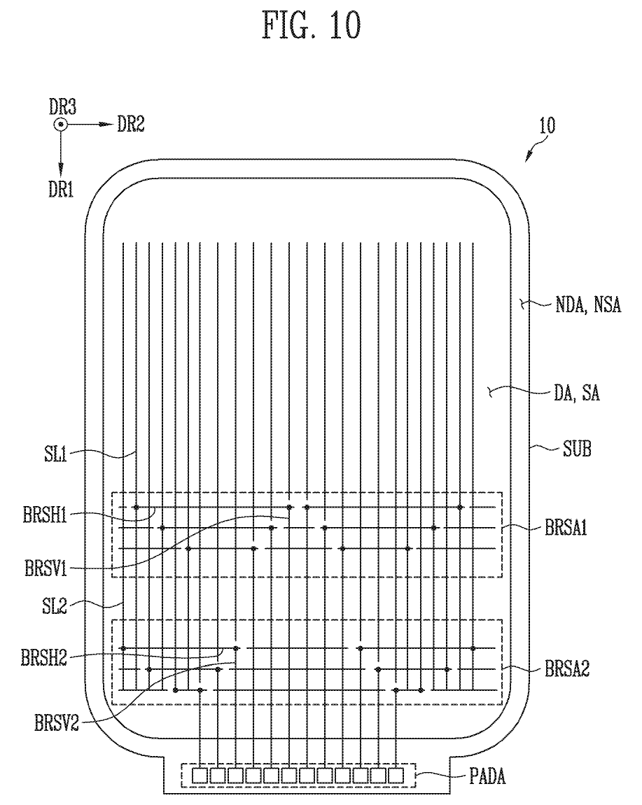

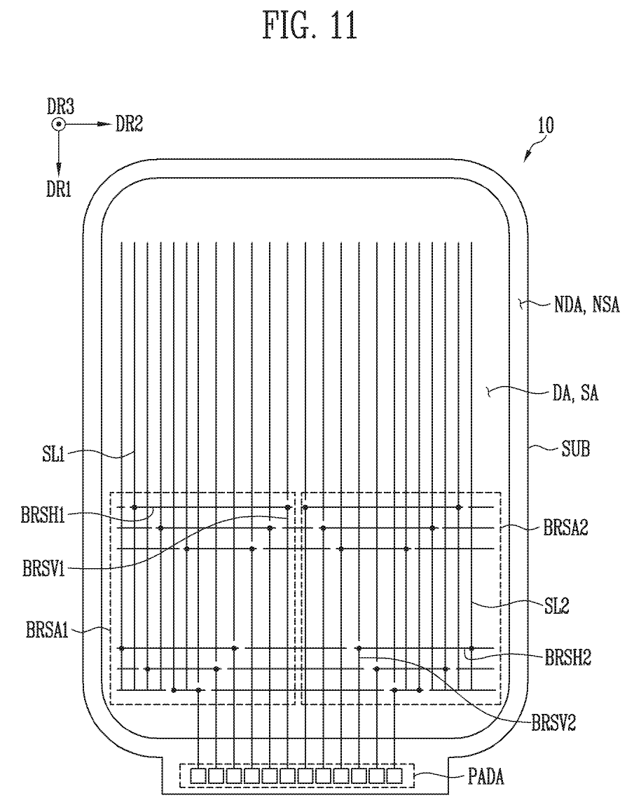

FIGS. 10 and 11 are diagrams illustrating a relationship between pads, connecting lines, and signal lines according to one or more embodiments of the present disclosure.

Referring to FIG. 10, a substrate SUB of a display device 10 may include a display area DA and a non-display area NDA. The display area DA may be an area where pixels PX are located, and the non-display area NDA may be an area where the pixels PX are not located. In addition, according to one or more embodiments, in case that the display device 10 includes optical sensors, the substrate SUB may include a sensing area SA and a non-sensing area NSA. The sensing area SA is an area where the optical sensors are located, and the non-sensing area NSA may be an area where the optical sensors are not located.

For example, size and shape of the display area DA may be the same as size and shape of the sensing area SA. In addition, size and shape of the non-display area NDA may be the same as size and shape of the non-sensing area NSA. However, in one or more other embodiments, the sensing area SA may be larger or smaller than the display area DA. Depending on the size of the sensing area SA, the non-sensing area NSA may be smaller or larger than the non-display area NDA.

Hereinafter, a plane orientation of the substrate SUB is defined with respect to the first direction DR1, and the second direction DR2 substantially perpendicular to the first direction DR1, and a vertical orientation of the substrate SUB is defined with respect to the third direction DR3. However, this is for the convenience of explanation, and the substrate SUB may be bent. For example, a portion of the substrate SUB that protrudes to the first direction DR1 includes a pad area PADA, where the protruding portion may be bent to reduce or minimize a dead space. In addition, by other sides surfaces of the substrate SUB being also bent, the display device 10 including a narrow bezel that reduces or minimizes the non-display area NDA may also be implemented.

The substrate SUB may include a first connection area BRSA1 and a second connection area BRSA2. The first connection area BRSA1 and the second connection area BRSA2 may commonly include signal lines SL1 and SL2 and the first connection lines BRSV1 and BRSV2 extending in the first direction DR1. The first connection area BRSA1 may include second connection lines BRSH1 extending in the second direction DR2. Meanwhile, the second connection area BRSA2 may include second connection lines BRSH2 extending in the second direction DR2.

The signal lines SL1 and SL2 may include data lines DL1 to DLm. In case that the display device 10 includes optical sensors, the signal lines SL1 and SL2 may include readout lines of the optical sensors. The signal lines SL1 and SL2 may extend continuously to the first direction DR1 without being disconnected in the middle.

On the other hand, the first connection lines BRSV1 and BRSV2 and the second connection lines BRSH1 and BRSH2 may be disconnected in the middle as suitable. The first connection lines BRSV1 and BRSV2 and the second connection lines BRSH1 and BRSH2 may transmit a signal to the signal lines SL1 and SL2 by being connected with the corresponding pads in the pad area PADA.

A corner of the substrate SUB may have an angular shape, but may also have a curved shape, as shown in FIG. 10. The curved shape of the corner makes it difficult to implement conventional fanout wiring structures. The second connection area BRSA2 enables a fanout free structure.

Meanwhile, the first connection area BRSA1 may be a readout connection area. For example, the second connection lines BRSH1 of the first connection area BRSA1 may be second readout connection lines connected to the readout lines of the optical sensors. For example, the first signal lines SL1 may be the readout lines. At this time, the first connection lines BRSV1 connected to the second connection lines BRSH1 in the first connection area BRSA1 may be first readout connection lines. One of the readout lines, one of the first readout connection lines, and one of the second readout connection lines may be connected to each other. Their connection order may be irrelevant, and “connected to each other” may mean connected to “the same electrical node.” Lines connected to the same electrical node will have the same voltage. By connecting the first connection lines BRSV1 with the corresponding pads, sensing currents received from the optical sensors may be transmitted to an integrated chip (IC) connected to the pads.

In addition, the second connection area BRSA2 may be a data connection area. For example, the second connection lines BRSH2 of the second connection area BRSA2 may be second data connection lines connected to the data lines DL1 to DLq of the pixels (see FIG. 1). For example, the second signal lines SL2 may be the data lines DL1 to DLq. At this time, the first connection lines BRSV2 connected to the second connection lines BRSH2 in the second connection area BRSA2 may be first data connection lines. One of the data lines, one of the first data connection lines, and one of the second data connection lines may be connected to each other. Their connection order may be irrelevant, and “connected to each other” may mean connected to “the same electrical node.” Lines connected to the same electrical node will have the same voltage. By connecting the first connection lines BRSV2 with the corresponding pads, the data voltages received from the IC may be transmitted to the pixels.

In FIG. 10, the second connection area BRSA2 is shown to be located in the first direction DR1 from the first connection area BRSA1. But this is only one example. For another example, the first connection area BRSA1 may also be configured to be located in the first direction DR1 from the second connection area BRSA2.

Meanwhile, the first connection area BRSA1 and the second connection area BRSA2 do not necessarily have to be spaced apart from each other in the first direction DR1. Referring to FIG. 11, the first connection area BRSA1 and the second connection area BRSA2 may also be spaced apart from each other in the second direction DR2.

In addition, in one or more other embodiments, there may be no distinction between the first connection area BRSA1 and the second connection area BRSA2. For example, by placing the second readout connection line and the second data connection line area arranged alternately in the first direction DR1, the distinction between the readout connection area and the data connection area may become meaningless.

However, in one or more embodiments, the display device 10 may further include an additional sensor layer on the top (e.g., in the third direction DR3) of the layer in which the pixels and the optical sensors are formed. The additional sensor layer may be a sensor layer for sensing a user’s touch and an active pen, and may be composed of various methods such as resistive type, capacitive type, electro-magnetic induction type (EMI), electro-magnetic resonance type (EMR), optical type, and the like. In one or more other embodiments, the additional sensor layer may also be located under the bottom (e.g., in a direction opposite to the third direction DR3) of the layer where the pixels and optical sensors are formed.

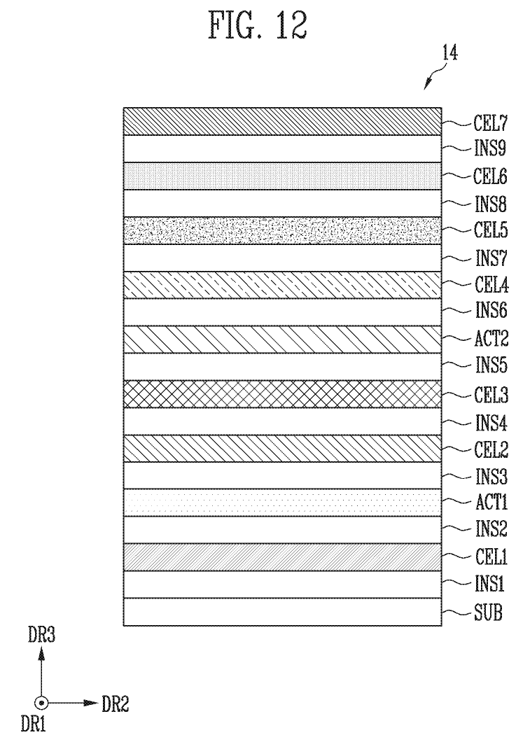

FIGS. 12 to 22 are diagrams illustrating a layout of a pixel unit according to one or more embodiments of the present disclosure.

Referring to FIG. 12, the pixel unit 14 according to one or more embodiments of the present disclosure may include a substrate SUB, a first insulating layer INS1 on the substrate SUB, a first conductive layer CEL1 on the first insulating layer INS1, a second insulating layer INS2 on the first conductive layer CEL1, a first active layer ACT1 on the second insulating layer INS2, a third insulating layer INS3 on the first active layer ACT1, a second conductive layer CEL2 on the third insulating layer INS3, a fourth insulating layer INS4 on the second conductive layer CEL2, a third conductive layer CEL3 on the fourth insulating layer INS4, a fifth insulating layer INS5 on the third conductive layer CEL3, a second active layer ACT2 on the fifth insulating layer INS5, a sixth insulating layer INS6 on the second active layer ACT2, a fourth conductive layer CEL4 on the sixth insulating layer INS6, a seventh insulating layer INS7 on the fourth conductive layer CEL4, a fifth conductive layer CEL5 on the seventh insulating layer INS7, an eighth insulating layer INS8 on the fifth conductive layer CEL5, a sixth conductive layer CEL6 on the eighth insulating layer INS8, a ninth insulating layer INS9 on the sixth conductive layer CEL6, and a seventh conductive layer CEL7 on the ninth insulating layer INS9 (as used herein, “on” or “located on” may mean “above”).

The substrate SUB may be made of a variety of materials, such as glass, polymers, and metals. The substrate SUB may be selected as one of a rigid substrate and a flexible substrate depending on an applicable product. In case that the substrate SUB is configured to include high molecular organics, the substrate SUB may consist of polystyrene, polyvinyl alcohol, polymethyl methacrylate, polyethersulfone, polyacrylate, polyethylene naphthalate, polyethylene terephthalate, polyphenylene sulfide, polyarylate, polyimide, polycarbonate, triacetate cellulose, cellulose acetate propionate, etc. On the other hand, the substrate SUB may be made of glass, fiber glass reinforced plastic (FRP), etc.

The first active layer ACT1 and the second active layer ACT2 may be semiconductor layers. For example, the first active layer ACT1 may consist of a polysilicon semiconductor, and the second active layer ACT2 may consist of an oxide semiconductor. The first active layer ACT1 may include channels, first electrodes, and second electrodes of polysilicon semiconductor transistors T1, T2, T5, T6, T7, and T8 (see FIG. 2). The second active layer ACT2 may include channels, first electrodes, and second electrodes of oxide semiconductor transistors T3 and T4. The first electrode and the second electrode of each transistor may be doped with impurities for conducting.

The conductive layers CEL1 to CEL7 may be composed of a single layer or multiple layers, and may be composed using known conductive materials, such as gold (Au), silver (Ag), aluminum (Al), molybdenum (Mo), chromium (Cr), titanium (Ti), nickel (Ni), neodymium (Nd), copper (Cu), and platinum (Pt).

The insulating layers INS1 to INS9 may be inserted to electrically separate, or insulate, the active layers ACT1 and ACT2 and the conductive layers CEL1 to CEL7. Through contact holes formed in each insulating layer INS1 to INS9, suitable electrode patterns may be connected to each other. The insulating layers INS1 to INS9 may consist of an organic insulating layer, an inorganic insulating layer, or an organic/inorganic insulating layer, and may consist of a single layer or may consist of multiple layers. For example, the insulating layers INS1 to INS9 may include at least one among silicon nitride (SiNx), silicon oxide (SiOx), silicon nitrate (SiOxNy), acryl resin, epoxy resin, phenolic resin, polyamide resin, or polyimide resin.

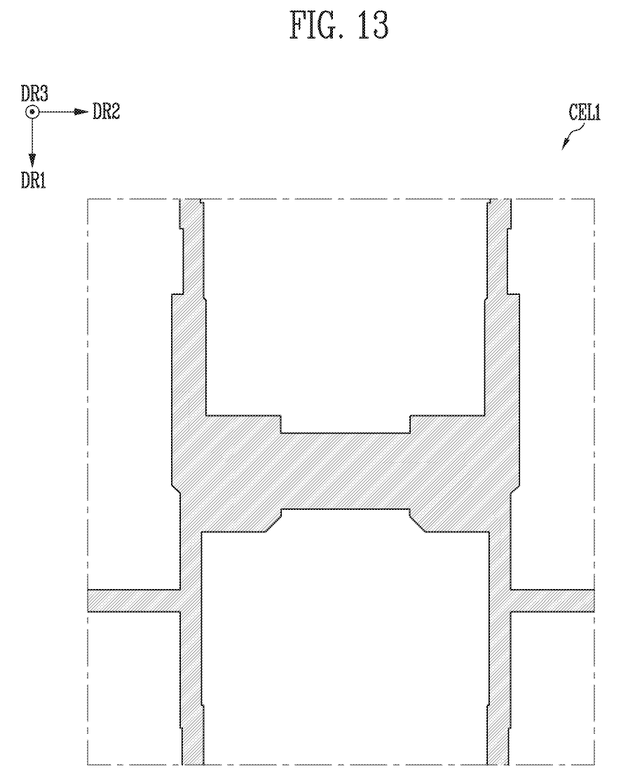

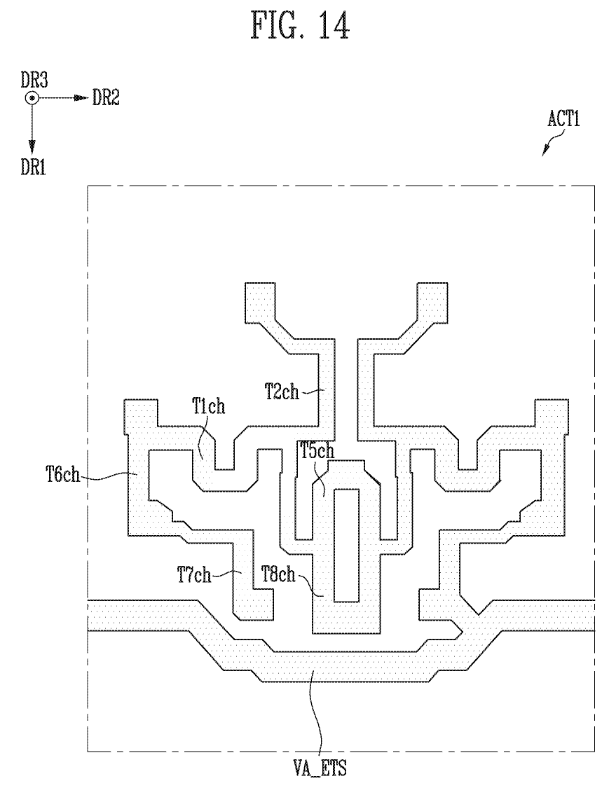

Referring to FIG. 13, a plan view of the first conductive layer CEL1 is shown. For example, the first power voltage ELVDD (see FIG. 2) may be provided to the first conductive layer CEL1. The first conductive layer CEL1 may include a sub-gate electrode of the first transistor T1.

Referring to FIG. 14, a plan view of the first active layer ACT1 is shown. For example, the first active layer ACT1 may include channels T1ch, T2ch, T5ch, T6ch, T7ch, and T8ch of the transistors T1, T2, T5, T6, T7, and T8.

According to one or more embodiments of the present disclosure, the first active layer ACT1 may include an etch-stop pattern VA_ETS. For example, the etch-stop pattern VA_ETS may extended in the second direction DR2. The etch-stop pattern VA_ETS may have an etch rate that is different from the insulating layers INS3 to INS7, or may include materials that are etched under different etching conditions.

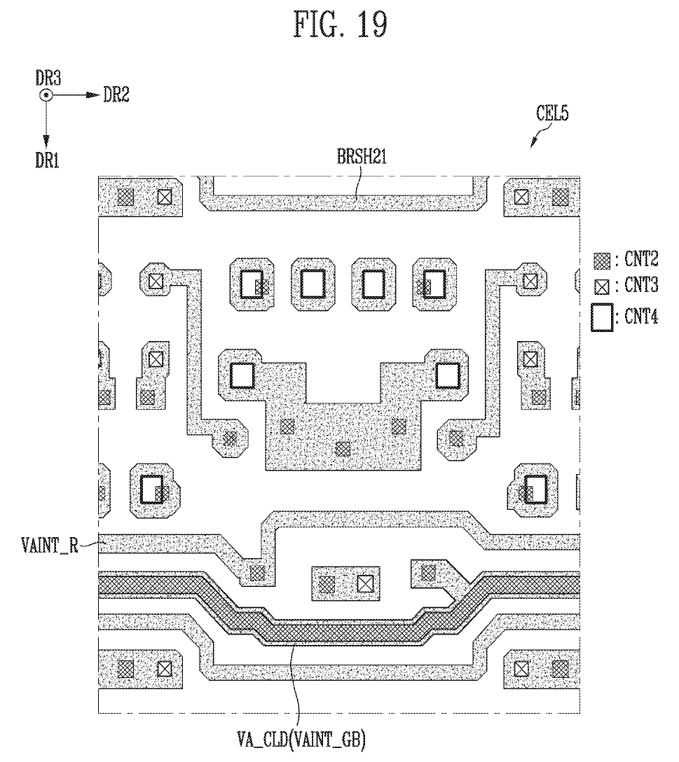

Cracks occurring under the etch-stop pattern VA_ETS may be reduced or minimized. In addition, the first active layer ACT1 may correspond to an optimal depth for the etch-stop pattern VA_ETS to be positioned. The deeper the depth at which inorganic layers are etched, the more stress generated by bending may be reduced or minimized. Therefore, the etch-stop pattern may also be configured to be located in the first conductive layer CEL1. However, to etch up to the top of the first conductive layer CEL1, the etching process may be suitable two or more times (see second contact hole CNT2 of FIG. 19). Therefore, in the display device 10 including the first active layer ACT1 and the second active layer ACT2, the etch-stop pattern VA_ETS included in the first active layer ACT1 has technical significance for its position.

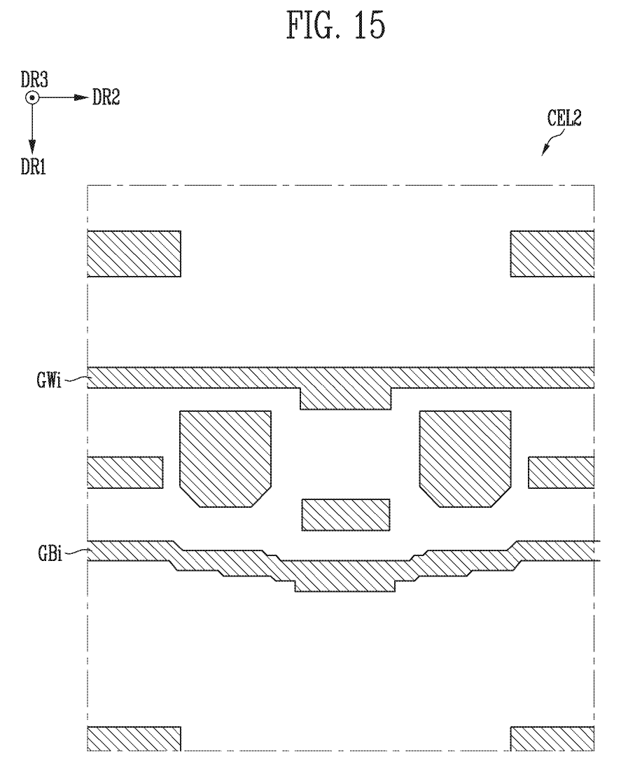

Referring to FIG. 15, a plan view of the second conductive layer CEL2 is shown. For example, the second conductive layer CEL2 may include the first scan line GWi and the second scan line GBi extending in the second direction DR2. In addition, the second conductive layer CEL2 may include a portion of the storage capacitor Cst (see FIG. 2).

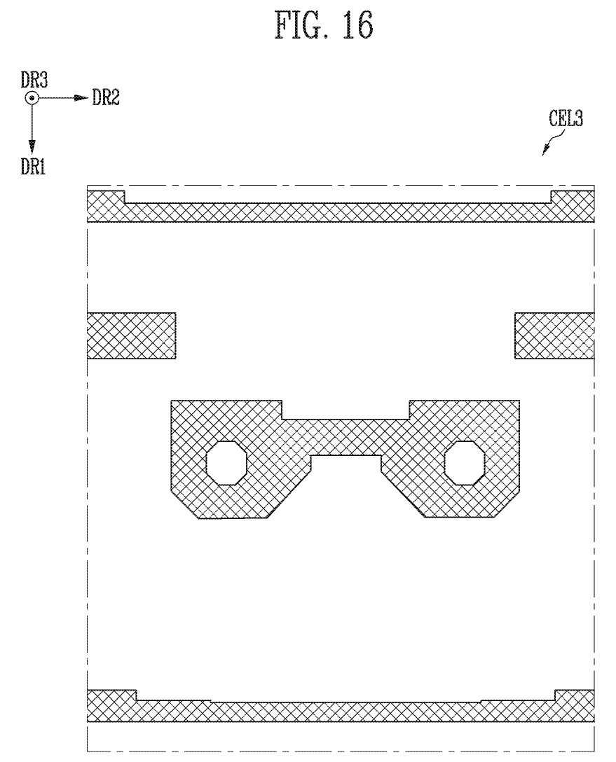

Referring to FIG. 16, a plan view of the third conductive layer CEL3 is shown. The third conductive layer CEL3 may include a portion of the storage capacitor Cst (see FIG. 2).

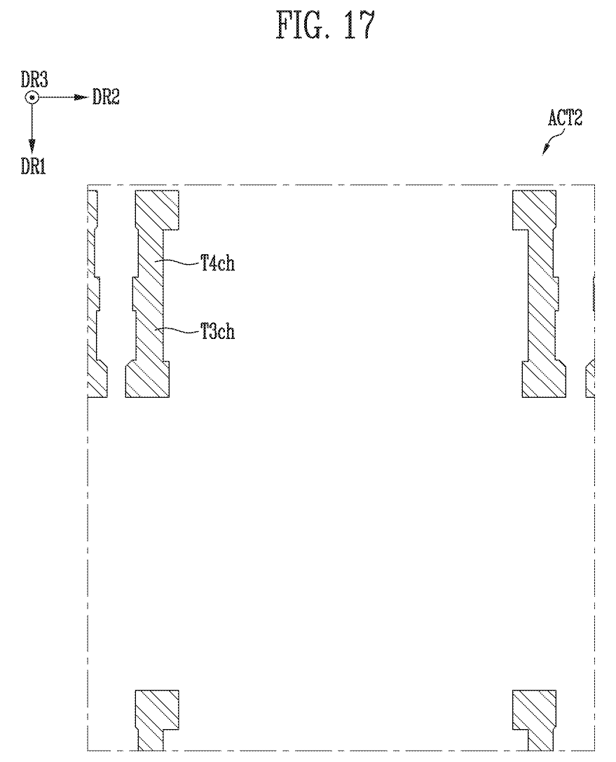

Referring to FIG. 17, a plan view of the second active layer ACT2 is shown. For example, the second active layer ACT2 may include channels T3ch and T4ch of transistors T3 and T4.

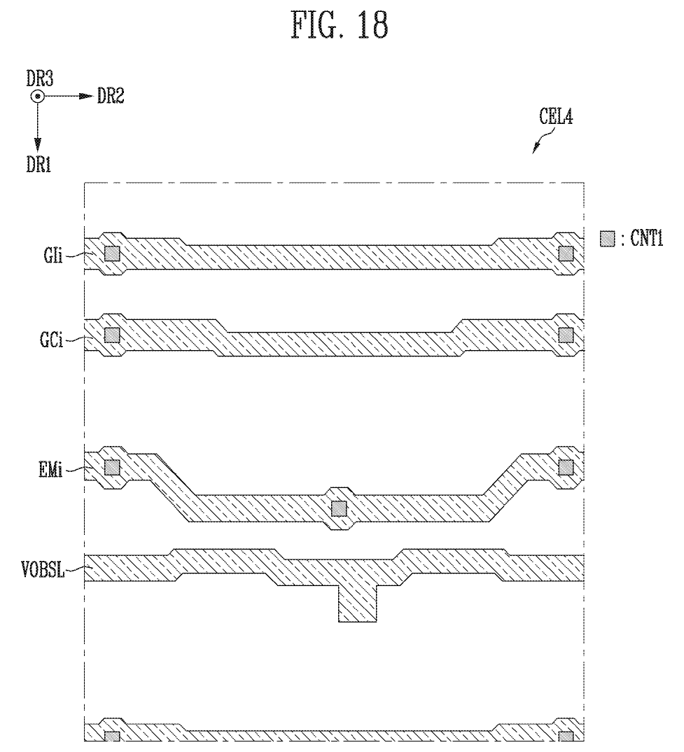

Referring to FIG. 18, a plan view of the fourth conductive layer CEL4 is shown. For example, the fourth conductive layer CEL4 may include the third scan line GIi, the fourth scan line GCi, the emission line EMi, and a bias voltage line VOBSL extending in the second direction DR2. The bias voltage VOBS (see FIG. 2) may be provided to the bias voltage line VOBSL.

Some patterns of the fourth conductive layer CEL4 may be connected to lower conductive layers CEL1, CEL2, and CEL3 or the first active layer ACT1 through first contact holes CNT1.

Referring to FIG. 19, a plan view of the fifth conductive layer CEL5 is shown. For example, the fifth conductive layer CEL5 may include a second connection line BRSH21, a second initialization voltage line VAINT_R, and a cover layer VA_CLD. For example, the second initialization voltage line VAINT_R and the cover layer VA_CLD may extend in the second direction DR2. The second connection line BRSH21 may correspond to a part of the second connection lines BRSH2 in FIGS. 10 and 11.

Some patterns of the fifth conductive layer CEL5 may be connected to the first active layer ACT1 through second contact holes CNT2. In addition, some patterns of the fifth conductive layer CEL5 may be connected to the second active layer ACT2 through third contact holes CNT3. Patterns of the fifth conductive layer CEL5 may be connected to the sixth conductive layer CEL6 through fourth contact holes CNT4.

The cover layer VA_CLD may contact an upper part of the etch-stop pattern VA_ETS of the first active layer ACT1 through a second contact hole CNT2. At this time, the second contact hole CNT2 may extend along an extension direction (e.g., second direction DR2) of the cover layer VA_CLD.

According to the cover layer VA_CLD of one or more embodiments, the occurrence of stringers (e.g., unintended metallic protrusions) on an upper part of the valley structure can be reduced, thereby reducing or preventing the likelihood of undesirable shorts.

In addition, the cover layer VA_CLD may function as a second initialization voltage line VAINT_GB. For example, the second initialization voltage line VAINT_R may supply the second initialization voltage VAINT to pixels of the first color, and the second initialization voltage line VAINT_GB may supply the second initialization voltage VAINT to pixels of the second color and the third color. For example, the first color may be red, the second color may be green, and the third color may be blue.

The total number of pixels of the second color and the third color may be greater than the total number of the pixels of the first color. The cover layer VA_CLD, compared to the second initialization voltage line VAINT_R, has a larger vertical area, which may make it suitable for supplying the second initialization voltage VAINT to a greater number of pixels of the second color and the third color. For example, the second initialization voltage VAINT provided to the second initialization voltage line VAINT_R and the second initialization voltage VAINT provided to the second initialization voltage line VAINT_GB may be the same or may differ from each other. Whether the second initialization voltages VAINT are the same may depend on the characteristics of the light-emitting elements of the first to third colors.

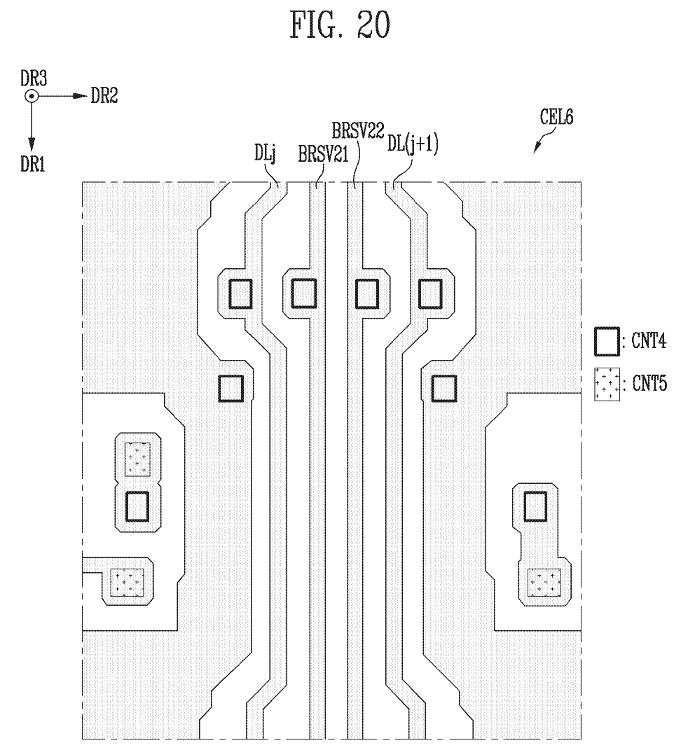

Referring to FIG. 20, a plan view of the sixth conductive layer CEL6 is shown. For example, the sixth conductive layer CEL6 may include data lines DLj and DL(j+1) and the first connection lines BRSV21 and BRSV22 that extend in the first direction DR1. The first connection lines BRSV21 and BRSV22 may correspond to portions of the first connection line BRSV2 in FIGS. 10 and 11. The data line DLj may be a data line connected to pixels located in a j-th column. The data line DL(j+1) may be a data line connected to the pixels located in (j+1)-th column.

Some patterns of the sixth conductive layer CEL6 may be connected to the fifth conductive layer CEL5 through fourth contact holes CNT4. Some patterns of the sixth conductive layer CEL6 may be connected to the seventh conductive layer CEL7 through fifth contact holes CNT5.

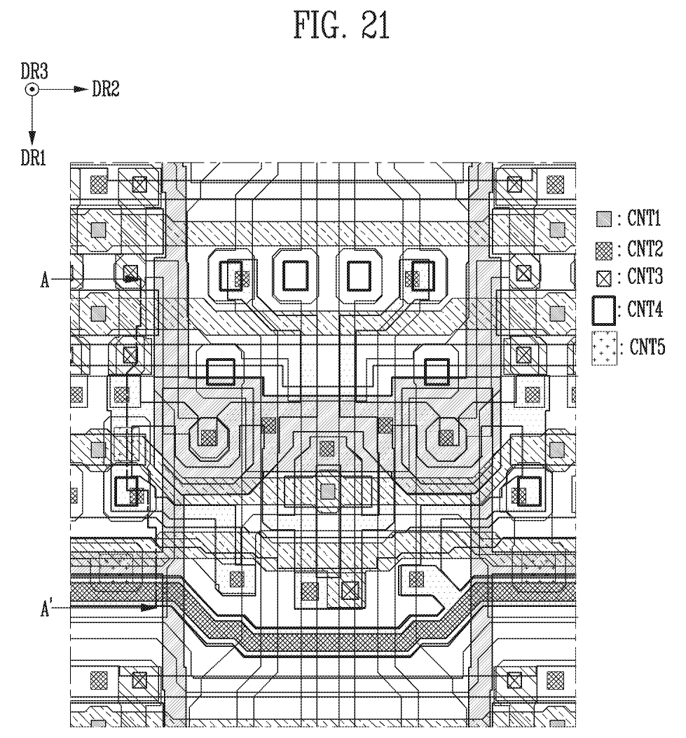

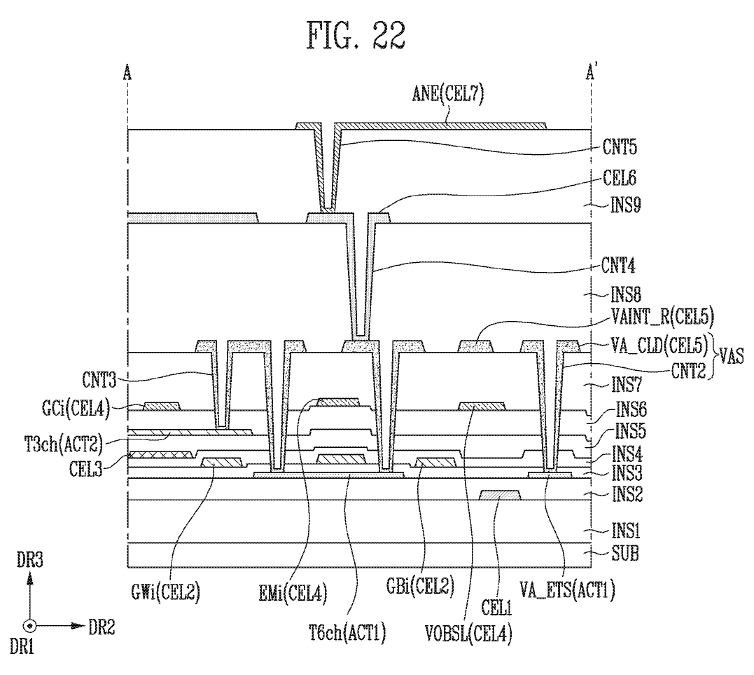

Referring to FIG. 21, a layout is shown in which the plan views of FIGS. 13 to 20 are overlapped.

Referring to FIG. 22, a cross-sectional view taken along the line A-A’ in FIG. 21 is shown. In describing FIG. 22, the description of the contents overlapping with FIGS. 12 to 21 is omitted.

A cross-section of the third transistor T3 including a channel T3ch located in the second active layer ACT2 and the sixth transistor T6 including a channel T6ch located in the first active layer ACT1 is illustratively shown (see FIG. 2). A second electrode of the sixth transistor T6, which is located in the first active layer ACT1, may be connected to an anode electrode ANE of the light-emitting element LD through the second contact hole CNT2, the fourth contact hole CNT4, and the fifth contact hole CNT5.

Valley structures VAS may be located between at least some of the pixels, and may penetrate a plurality of insulating layers INS3, INS4, INS5, INS6, and INS7. For example, the insulating layers INS3, INS4, INS5, INS6, and INS7 may be composed of inorganic layer. Even if the display device 10 is bent by the valley structure VAS, the occurrence of cracks may be reduced or minimized by increasing or maximizing the dispersion of stress.

The channel T6ch of the sixth transistor T6 may be spaced apart from the substrate SUB by a first distance. For example, the substrate SUB and the first active layer ACT1 may be separated by the first distance.

The channel T3ch of the third transistor T3 may be spaced apart from the substrate SUB by a second distance. For example, the substrate SUB and the second active layer ACT2 may be separated by the second distance.

A lower part of the valley structure VAS may be spaced apart from the substrate SUB by a third distance. At this time, the second distance may be greater than the first distance and the third distance, respectively. In addition, the first distance and the third distance may be different from each other.

For example, the valley structure VAS may include the second contact hole CNT2. As described above, the second contact holes CNT2 are etched holes formed to connect some patterns of the fifth conductive layer CEL5 with the first active layer ACT1. Therefore, a separate additional process may not be required to create the valley structure VAS.

Therefore, the lower part of the valley structure VAS may contact an upper part of the first active layer ACT1. In FIG. 22, the third distance may be equal to a distance between the upper part of the first active layer ACT1 (e.g., the upper part of the etch-stop pattern VA_ETS) and the substrate SUB. The first distance may be equal to a distance between a bottom of the first active layer ACT1 and the substrate SUB. Therefore, the first distance and the third distance may be different. For example, the third distance may be greater than the first distance. The first active layer ACT1 may include the etch-stop pattern VA_ETS. The etch-stop pattern VA_ETS may reduce or minimize cracks occurring under the etch-stop pattern VA_ETS. In addition, the first active layer ACT1 may correspond to an optimal depth for the etch-stop pattern VA_ETS to be located. The deeper the depth at which inorganic layers are etched, the more stress generated by bending may be reduced or minimized. Therefore, the etch-stop pattern may also be configured to be located in the first conductive layer CEL1. However, to etch up to the top of the first conductive layer CEL1, the etching process may be suitable two or more times (see second contact hole CNT2 of FIG. 19). Therefore, in the display device 10 including the first active layer ACT1 and the second active layer ACT2, the etch-stop pattern VA_ETS included in the first active layer ACT1 has technical significance for its position.

An upper part of the valley structure VAS may be spaced apart from the substrate SUB by a fourth distance. The fourth distance may be equal to a distance between the fifth conductive layer CEL5 and the substrate SUB. Therefore, the fourth distance may be greater than the second distance.

The valley structure VAS may include a cover layer VA_CLD covering the upper part, the lower part, and side walls of the valley structure VAS and including conductive material. According to the cover layer VA_CLD of one or more embodiments, the generation or occurrence of stringers (e.g., unintended metallic protrusions) on the upper part of the valley structure can be reduced, thereby reducing or preventing the likelihood of undesirable electrical shorts.

As described above, the initialization voltage may be provided to the cover layer VA_CLD. The cover layer VA_CLD may function as the second initialization voltage line VAINT_GB (see FIG. 19). For example, the second initialization voltage line VAINT_R may supply the second initialization voltage VAINT to the pixels of the first color, and the second initialization voltage line VAINT_GB may supply the second initialization voltage to the pixels of the second color and the third color. For example, the first color may be red, the second color may be green, and the third color may be blue. The total number of pixels in the second color and the third color may be greater than the total number of the pixels of the first color. The cover layer VA_CLD, compared to the second initialization voltage line VAINT_R, has a larger vertical area, which makes the cover layer VA_CLD suitable for supplying the second initialization voltage VAINT to a greater number of pixels corresponding to the second color and the third color. For example, the second initialization voltage VAINT provided to the second initialization voltage line VAINT_R and the second initialization voltage VAINT provided to the second initialization voltage line VAINT_GB may be the same or may be different from each other. Whether the second initialization voltages VAINT are the same may depend on the characteristics of the light-emitting elements in the first to third colors.

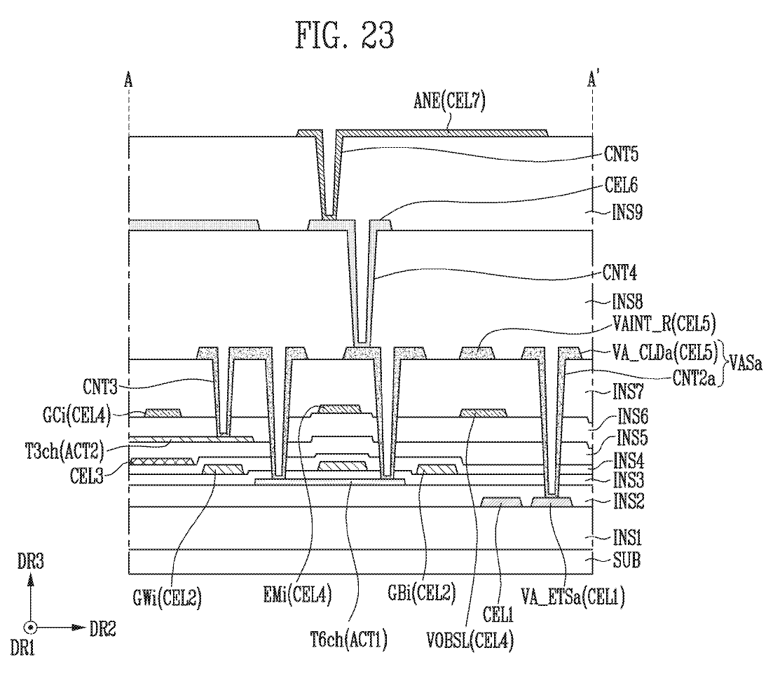

FIGS. 23 to 26 are diagrams illustrating a valley structure according to one or more other embodiments of the present disclosure. In describing by reference to FIGS. 23 to 26, the repeated description of the contents overlapping with FIG. 22 is omitted.

Referring to FIG. 23, a lower part of a valley structure VASa may contact an upper part of a first conductive layer CEL1 between a substrate SUB and a first active layer ACT1. Some patterns of the first conductive layer CEL1 may be included as an etch-stop pattern VA_ETSa. A cover layer VA_CLDa may contact an upper part of the etch-stop pattern VA_ETSa through a second contact hole CNT2a. The second contact hole CNT2a may penetrate up to a second insulating layer INS2, which is an inorganic layer, which may be more effective in stress dispersion of the display device 10.

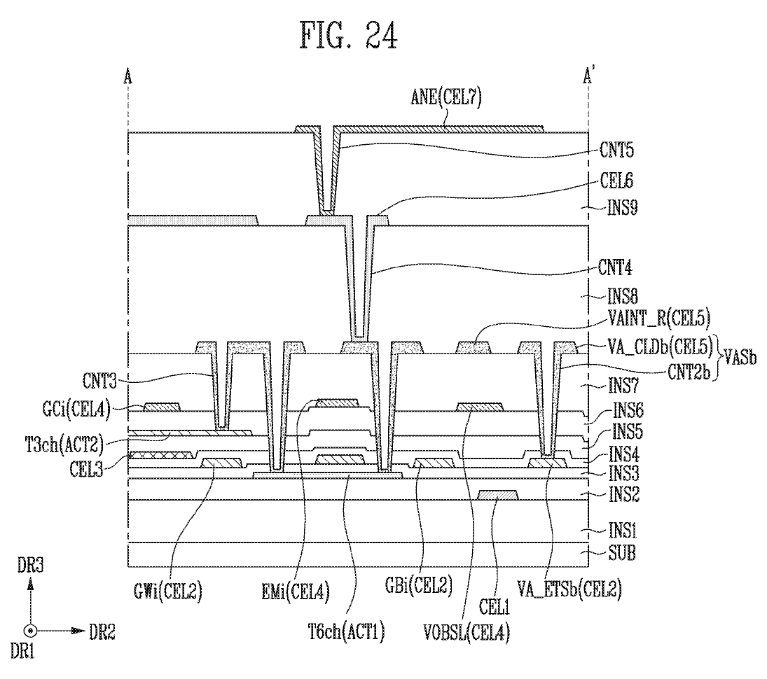

Referring to FIG. 24, a lower part of the valley structure VASb may contact an upper part of a second conductive layer CEL2, which is located between the first active layer ACT1 and a second active layer ACT2. Some patterns of the second conductive layer CEL2 may be included as an etch-stop pattern VA_ETSb. A cover layer VA_CLDb may contact an upper part of the etch-stop pattern VA_ETSb through a second contact hole CNT2b. Various conductive layers may be included as the etch-stop pattern VA_ETSb.

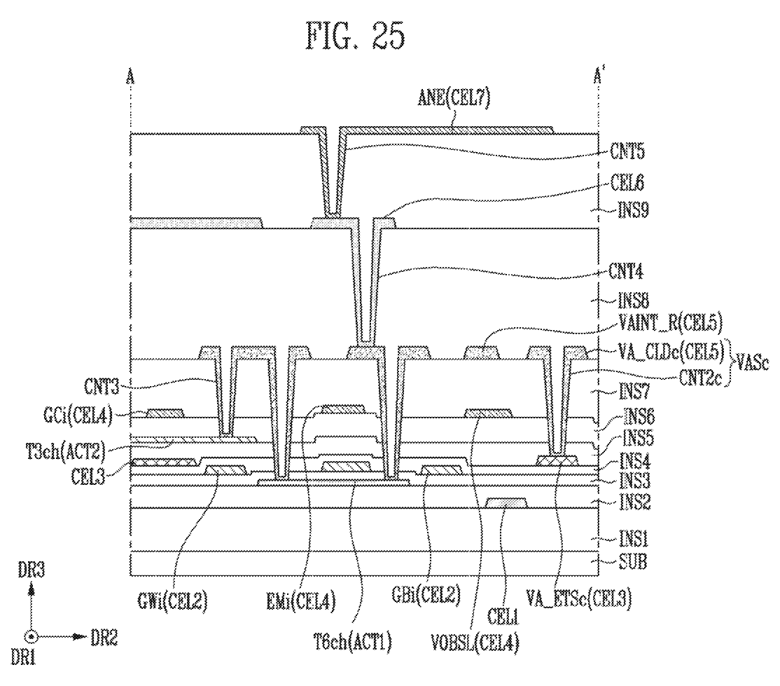

Referring to FIG. 25, a lower part of a valley structure VASc may contact an upper part of the third conductive layer CEL3, which is located between the first active layer ACT1 and the second active layer ACT2. Some patterns of the third conductive layer CEL3 may be included as an etch-stop pattern VA_ETSc. A cover layer VA_CLDc may contact an upper part of the etch-stop pattern VA_ETSc through a second contact hole CNT2c. Various conductive layers may be included as the etch-stop pattern VA_ETSc.

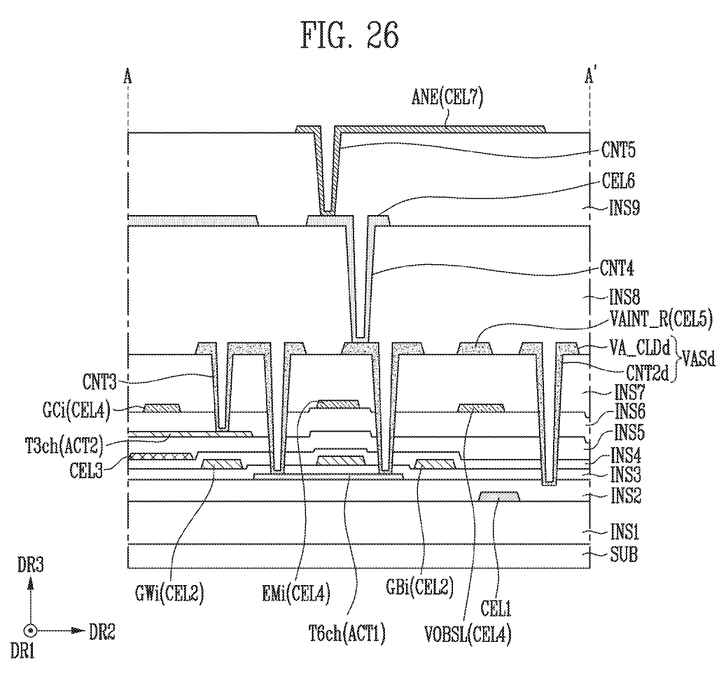

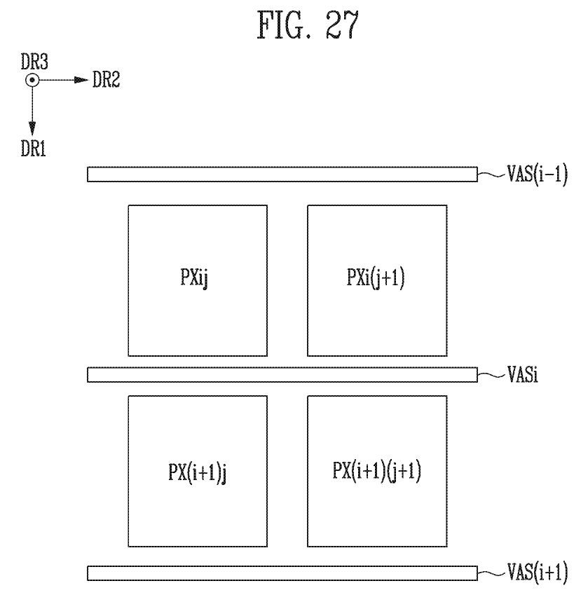

Referring to FIG. 26, the display device 10 may not include, or may omit, an etch-stop pattern. As described above, more than two etching processes may be suitable to etch from the seventh insulating layer INS7 to the second insulating layer INS2. Therefore, even if a second contact hole CNT2d is etched only once without an etch-stop pattern, a lower part of a valley structure VASd may be located in the third direction DR3 of the first conductive layer CEL1.

Referring to FIG. 26, it is explained that various conductive layers or active layers may include an etch-stop pattern. In addition, other conductive layers or active layers may also include the etch-stop pattern.

In addition, referring to FIGS. 22 to 26, a valley structure is described to include a cover layer in the fifth conductive layer CEL5. In addition, other conductive layers or active layers may also include the cover layer. However, in one or more other embodiments, the display device 10 may not include, or may omit, a cover layer.

FIGS. 27 to 32 are diagrams to illustrate a relationship between pixels and valley structures according to embodiments of the present disclosure.

The display device 10 may include a plurality of valley structures VAS(i-1), VASi, VAS(i+1), VAS(i-1)’, VASi’, VAS(i+1)’, VAS(j-1), VASj, VAS(j+1), VAS(j-1)’, VASj’, and VAS(j+1)’, etc. Pixels PXij, PXi(j+1), PX(i+1)j, and PX(i+1)(j +1), etc. may be arranged in the first direction DR1 and the second direction DR2.

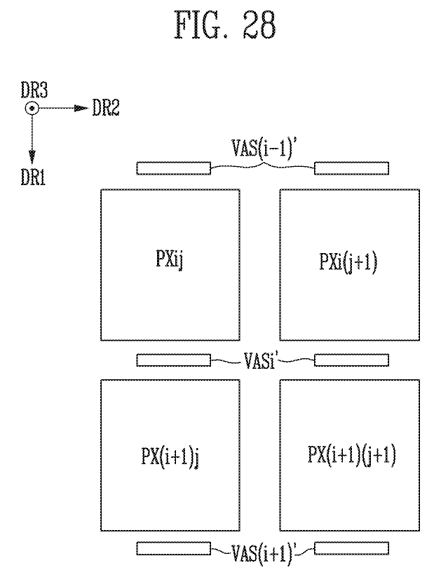

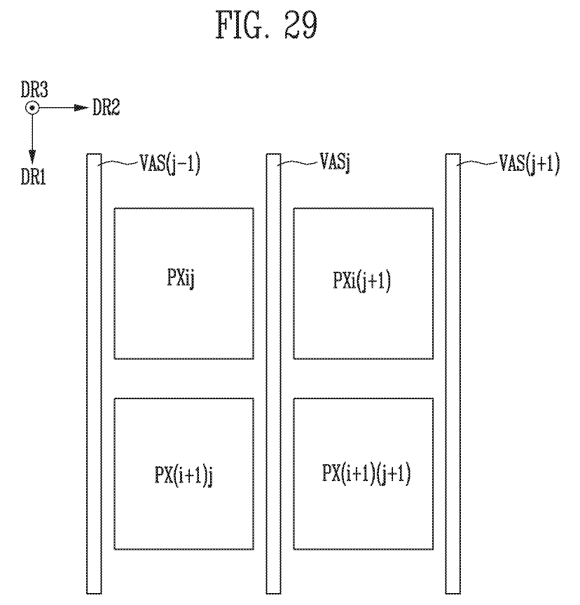

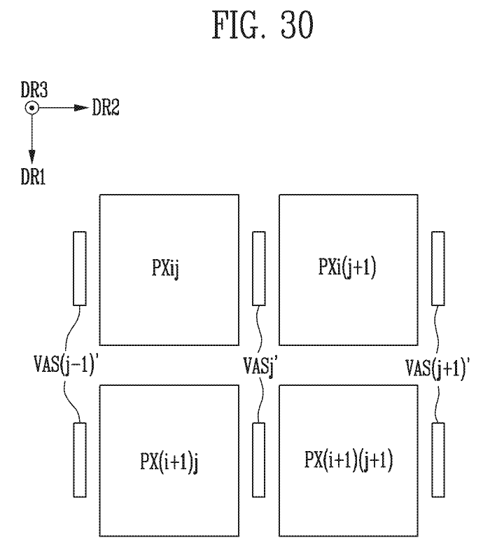

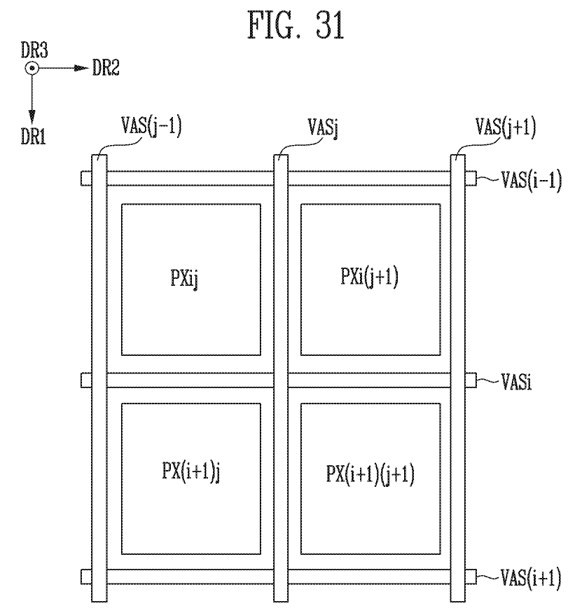

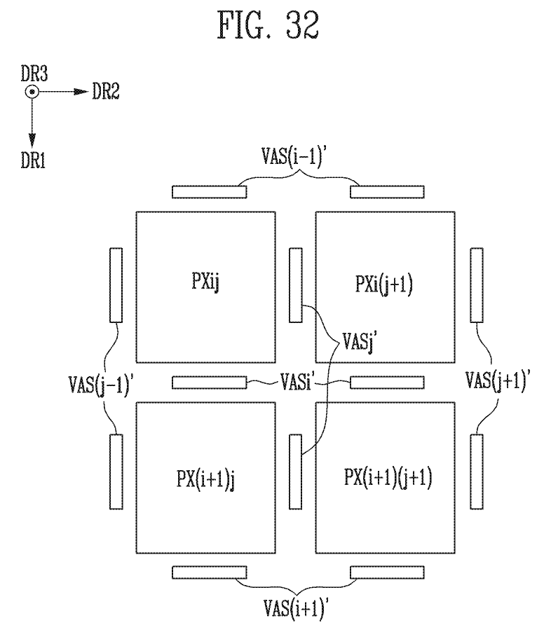

The plurality of valley structures VAS(i-1) to VAS(j+1)’ may extend in at least one of the first direction DR1 or the second direction DR2. For example, referring to FIGS. 27 and 28, the valley structures VAS(i-1), VASi, VAS(i+1), VAS(i-1)’, VASi’, and VAS(i+1)’ may extend in the second direction DR2. Meanwhile, referring to FIGS. 29 and 30, the valley structures VAS(j-1), VASj, VAS(j+1), VAS(j-1)’, VASj’, and VAS(j+1)’ may extend in the first direction DR1. Meanwhile, referring to FIGS. 31 and 32, the valley structures VAS(i-1), VASi, VAS(i+1), VAS(i-1)’, VASi’, VAS(i+1)’, VAS(j-1), VASj, VAS(j+1), VAS(j-1)’, VASj’, and VAS(j+1)’ may extend in the first direction DR1 and in the second direction DR2 (e.g., respectively).

Referring to FIGS. 27, 29, and 31, with respect to a direction in which the plurality of valley structures VAS(i-1), VASi, VAS(i+1), VAS(j-1), VASj, and VAS(j+1) extend, a length of each of the plurality of valley structures VAS(i-1), VASi, VAS(i+1), VAS(j-1), VASj, and VAS(j+1) may be greater than a length of each of the pixels (e.g., in plan view).

Referring to FIGS. 28, 30, and 32, with respect to the plurality of valley structures VAS(i-1)’, VASi’, VAS(i+1)’, VAS(j-1)’, VASj’, and VAS (j+1)’, a length of each of the plurality of valley structures VAS(i-1)’, VASi’, VAS(i+1)’, VAS(j-1)’, VASj’, and VAS (j+1)’ may be less than a length of each of the pixels (e.g., in plan view).

In the embodiments of FIGS. 27 to 32, the spacing between adjacent valley structures is configured to include one pixel. However, in one or more other embodiments, the spacing between adjacent valley structures may be configured to include two or more pixels.

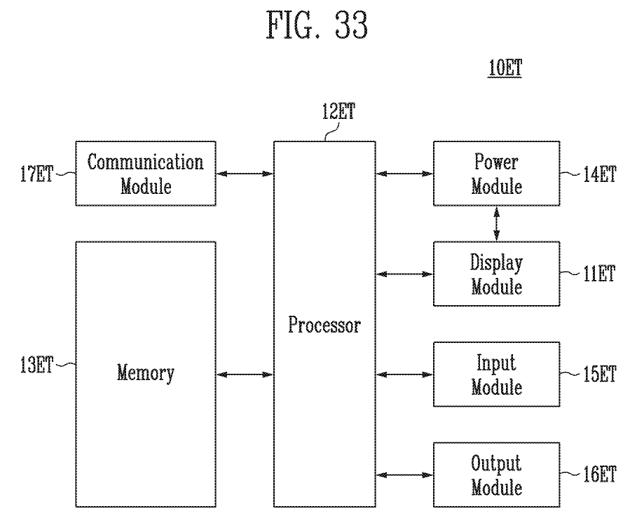

FIG. 33 is a block diagram of the electronic device according to one or more embodiments. Referring to FIG. 33, the electronic device 10ET according to one or more embodiments may include a display module 11ET, a processor 12ET, a memory 13ET, and a power module 14ET. The display module 11ET may also be represented as a display device.

A processor 12ET may include at least one among a central processing unit (CPU), an application processor (AP), a graphic processing unit (GPU), a communication processor (CP), an image signal processor (ISP), or a controller. In one or more embodiments, the processor 12ET may be provided divided into two or more from a functional or structural viewpoint. For example, the processor 12ET may include a main processor in the form of a first drive chip including a central processing unit, and an auxiliary process in the form of a second drive chip including a controller that receives an image signal from the main processor and processes the image signal to conform to an interface specification of the display module 11ET. The processor 12ET may provide image data. The display module 11ET may display an image based on grayscales of the image data.

The memory 13ET may include at least one of non-volatile memory or volatile memory. The memory 13ET may store data information suitable for operation of the processor 12ET or the display module 11ET. When the processor 12ET runs an application stored in memory 13ET, an image data signal and/or an input control signal may be transmitted to the display module 11ET, and the display module 11ET may process the signal provided and output image information through a display screen.

The power module 14ET may include a power supply module, such as a power adapter or a battery device, etc., and a power conversion module that converts the power supplied by the power supply module to generate the power suitable for the operation of the electronic device 10ET. Power conversion by the power conversion module may include DC-DC conversion, AC-DC conversion, and DC-AC conversion, but is not limited thereto.

The electronic device 10ET may further include an input module 15ET, a non-image output module 16ET, and/or a communication module 17ET.

The input module 15ET may provide input information to the processor 12ET and/or the display module 11ET. The input module 15ET may include various sensor modules as well as a physical button, a keyboard, and a microphone. Examples of the sensor modules may include a biometric sensor, such as a blood pressure sensor, a blood glucose sensor, an electrocardiogram sensor, a heart rate sensor, etc., as well as a touch sensor, a pressure sensor, a distance sensor, a position sensor, a digitizer, a motion recognition sensor, a camera sensor, a photoelectric sensor, a photoelectric conversion sensor, and a temperature sensor.

The non-image output module 16ET may receive information other than the image delivered from the processor 12ET and serve the role of providing it to the user. Examples of the non-image output module 16ET may include an acoustic module, a spectroscopic module, a light-emitting module, etc., and may include other functional modules unique to the electronic device (e.g., a cooling module of a refrigerator, etc.).

The communication module 17ET may be a module responsible for transmission and reception of information between the electronic device 10ET and an external device, and may include a receiver and a transmitter. The communication module 17ET may include various wireless communication modules, such as a mobile communication module, a Wi‑Fi® module, or a Bluetooth® module (Wi‑Fi® being a registered trademark of the non-profit Wi-Fi Alliance, and Bluetooth® being a registered trademark of Bluetooth Sig, Inc., Kirkland, WA), etc., but may also include various wired communication modules.

At least one of each of components of the electronic device 10ET described above may be included within the display device according to the embodiments described above. In addition, some of the individual modules functionally included within one module may be included within the display device and others may be provided separately from the display device. For example, the display device may include the display module 11ET, and the processor 12ET, the memory 13ET, and the power module 14ET may be provided in the form of other devices within the electronic device 10ET that are not display devices. As another example, the power module 14ET may be arranged within a display device and may also supply power to the processor 12ET and the memory 13ET provided within the electronic device 10ET that is not the display device, but is not limited to the examples above.

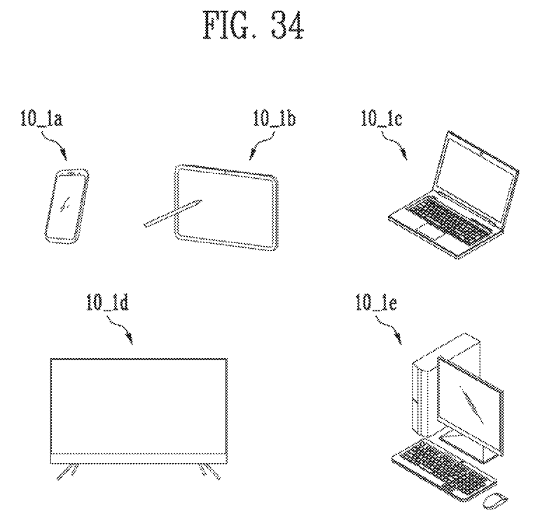

FIGS. 34 to 36 are schematic diagrams of an electronic device according to various embodiments. FIGS. 34 to 36 show examples of various electronic devices to which display devices according to embodiments are applied.

FIG. 34 shows a smartphone 10_1a, a tablet PC 10_1b, a laptop 10_1c, a TV 10_1d, and a desk monitor 10_1e as examples of the electronic devices.

The smartphone 10_1a may include an input module, such as a touch sensor, etc., and a communication module, in addition to the display modules 11ET. The smartphone 10_1a may process information received through the communication module or other input module and display information through the display module of the display device.

The tablet PC 10_1b, the laptop 10_1c, the TV 10_1d, and the desk monitor 10_1e may also include the display module and the input module similar to the smartphone 10_1a, and may further include the communication module in some cases.

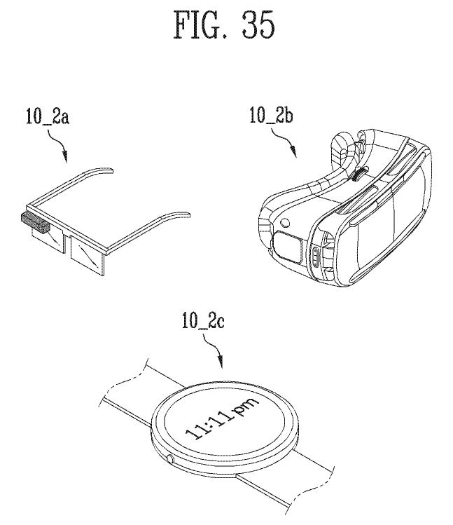

FIG. 35 illustrates an example where an electronic device including a display module is applied to a wearable electronic device. The wearable electronic device may be a smart glasses 10_2a, a head mounted display 10_ 2b, a smart watch 10_2c, etc.

The smart glasses 10_2a and the head mounted display 10_2b may include a display module that emits a display image and a reflector that reflects the emitted display screen and provides it to the user's eyes, thereby providing the user with a screen of virtual reality or augmented reality.

The smart watch 10_2c may include a biometric sensor as an input device, and may provide biometric information recognized through the biometric sensor to the user through the display module.

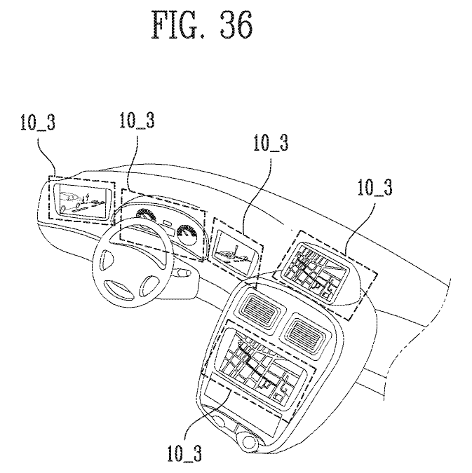

FIG. 36 illustrates an example where an electronic device including a display module is applied to an automobile. For example, an electronic device 10_3 may be applied to an instrument panel, a center fascia, etc. of an automobile, or be applied to a center information display (CID) placed on a dashboard of an automobile or to a room mirror display that replace a side mirror.

In one or more embodiments, the electronic devices to which the display device according to embodiments is applied may include not only devices that mainly focus on screen display, such as a billboard, a light panel, a game machine, etc., but also various home appliances that display information through the display module, such as a refrigerator, a washing machine, a dryer, an air conditioner, a robot cleaner, etc. In addition, in case that the display module has function of transmitting light, a smart window or a transparent display device that display a background and a display image together may be applied to the electronic device. The types of electronic devices according to one or more embodiments are not limited by those described above, and the application of other various electronic devices not described may also be possible.

The drawings referenced so far and the detailed description of the disclosure described are only illustrative of the present disclosure and they have been used solely for the purpose of describing the present disclosure, and not to limit its meaning or to limit the scope of the present disclosure described in claims. Therefore, those skilled in the art will understand that various variations and equivalent other embodiments are possible from this. Therefore, the true technical protection scope of the present disclosure will have to be determined by the technical idea of the attached claims, with functional equivalents thereof to be included therein.

What is claimed is:

1. A display device comprising:
a substrate;
pixels above the substrate, and comprising:
a first transistor comprising a channel in a first active layer spaced from the substrate by a first distance; and
a second transistor comprising a channel in a second active layer spaced from the substrate by a second distance that is greater than the first distance; and
a valley structure between some of the pixels, penetrating insulating layers, and having a lower part spaced from the substrate by a third distance that is less than the second distance and different from the first distance.

2. The display device of claim 1, wherein the lower part of the valley structure contacts an upper part of the first active layer.

3. The display device of claim 1, wherein the lower part of the valley structure contacts an upper part of a first conductive layer between the substrate and the first active layer.

4. The display device of claim 1, wherein the lower part of the valley structure contacts an upper part of a second conductive layer between the first active layer and the second active layer.

5. The display device of claim 4, wherein the second conductive layer comprises a scan line comprising a gate electrode of the first transistor.

6. The display device of claim 1, wherein an upper part of the valley structure is spaced from the substrate by a fourth distance that is greater than the second distance.

7. The display device of claim 6, wherein the valley structure comprises a cover layer covering an upper part, a lower part, and a side wall and comprising conductive material.

8. The display device of claim 7, wherein the cover layer is configured to receive an initialization voltage.

9. The display device of claim 1, further comprising valley structures comprising the valley structure,
wherein the pixels are arranged in a first direction, and in a second direction substantially perpendicular to the first direction,
wherein the valley structures extend in at least one of the first direction or the second direction, and
wherein a length of the valley structures is greater than a length of the pixels.

10. The display device of claim 1, further comprising valley structures comprising the valley structure,
wherein the pixels are arranged in a first direction, and in a second direction substantially perpendicular to the first direction,
wherein the valley structures extend in at least one of the first direction or the second direction, and
wherein a length of the valley structures is less than a length of the pixels.

11. An electronic device comprising:
a processor for providing an image data; and
a display device for displaying an image based on grayscales of the image data, and comprising:
a substrate;
pixels above the substrate and comprising:
a first transistor comprising a channel in a first active layer spaced from the substrate by a first distance; and
a second transistor comprising a channel in a second active layer spaced from the substrate by a second distance that is greater than the first distance; and
a valley structure between some of the pixels, penetrating insulating layers, and having a lower part spaced from the substrate by a third distance that is less than the second distance and that is different from the first distance.

12. The electronic device of claim 11, wherein the lower part of the valley structure contacts an upper part of the first active layer.

13. The electronic device of claim 11, wherein the lower part of the valley structure contacts an upper part of a first conductive layer between the substrate and the first active layer.

14. The electronic device of claim 11, wherein the lower part of the valley structure contacts an upper part of a second conductive layer between the first active layer and the second active layer.

15. The electronic device of claim 14, wherein the second conductive layer comprises a scan line comprising a gate electrode of the first transistor.

16. The electronic device of claim 11, wherein an upper part of the valley structure is spaced from the substrate by a fourth distance that is greater than the second distance.

17. The electronic device of claim 16, wherein the valley structure comprises a cover layer covering an upper part, a lower part, and a side wall and comprising conductive material.

18. The electronic device of claim 17, wherein the cover layer is configured to receive an initialization voltage.

19. The electronic device of claim 11, wherein the display device comprises valley structures comprising the valley structure,
wherein the pixels are arranged in a first direction, and in a second direction substantially perpendicular to the first direction,
wherein the valley structures extend in at least one of the first direction or the second direction, and
wherein a length of the valley structures is greater than a length of the pixels.

20. The electronic device of claim 11, wherein the display device comprises valley structures comprising the valley structure,
wherein the pixels are arranged in a first direction and in a second direction substantially perpendicular to the first direction,
wherein the valley structures extend in at least one of the first direction or the second direction, and
wherein a length of the valley structures is less than a length of the pixels.
